(19) United States
(12) Patent Application Publication
(10) Pub. No.: US 2008/0211005 A1
(43) Pub. Date: Sep. 4, 2008

(54) SEMICONDUCTOR DEVICE

(76) Inventor: Hiroshi AKAHORI, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/965,008

(22) Filed: Dec. 27, 2007

(30) Foreign Application Priority Data
Dec. 28, 2006 (JP) 2006-354852

(51) Int. Cl. H01L 27/115; H01L 21/8247

(52) U.S. Cl. 257/316; 438/257; 257/E27.103; 257/E21.681

(57) ABSTRACT

There is provided a MOSFET-type semiconductor device having a coating insulating film formed to cover the surface portions of MOS transistors formed on a semiconductor substrate. The insulating film is formed of a silicon nitride film or silicon oxynitride film and the ratio (N—H/Si—H) of the density of N—H bonds to the density of Si—H bonds in the insulating film is set to 3 or less.

### CROSS-REFERENCE TO RELATED APPLICATIONS

This application is based upon and claims the benefit of priority from prior Japanese Patent Application No. 2006-354852, filed Dec. 28, 2006, the entire contents of which are incorporated herein by reference.

### BACKGROUND OF THE INVENTION

1. Field of the Invention

This invention relates to a semiconductor device, and more particularly, to a semiconductor device having an improved coating insulating film.

2. Description of the Related Art

Recently, nonvolatile memory cells with the double-layered gate structures each having a floating gate and control gate stacked on a semiconductor substrate are used as memory cells of a nonvolatile semiconductor memory device that electrically performs the data write/erase operation. In this type of the nonvolatile semiconductor memory device, it is known that a silicon nitride film (SiN film) that is one of the constituent materials of the device gives an influence to the reliability thereof.

The SiN film is formed on the side walls of transistors that form a memory cell and used as an implantation mask. The film is used to protect the transistors from metal impurities and B and P in the interlayer insulating film and is called a liner SiN film. Further, the film is also used to cover the entire portion of the transistors in order to block the metal impurities diffused in the back end of line (BEOL) step and is called a barrier SiN film. The above SiN films are formed by use of a low-pressure CVD method using normal dichlorosilane (DCS: SiH₂Cl₂) and ammonium (NH₃) gas (refer to Jpn. Pat. Appln. KOKAI Publication No. 2002-198526). In the following description, a nitride film formed by use of the above method is simply expressed by a DCS-SiN film.

When a nonvolatile semiconductor memory device is formed by use of a DCS-SiN film, there occurs a problem that the reliability property, more specifically, the charge holding characteristic and threshold value variation amount (endurance characteristic) become worse. Therefore, conventionally, the reliability is enhanced by reducing the hydrogen in the SiN film by performing a heat treatment, for example, a wet oxidation (vapor oxidation) process with respect to the DCS-SiN film after film formation.

It is considered that active hydrogen is discharged from the film by the heat treatment or the like in the BEOL process and causes faults to occur in the tunnel insulating film of the nonvolatile memory cell when the wet oxidation process is not used after film formation of the DCS-SiN film. Specifically, it is considered that if active hydrogen is introduced into the tunnel insulating film, the active hydrogen breaks Si—O bonds in the film and causes the number of dangling bonds to increase. Particularly, the bonds are damaged in the interface between silicon and the tunnel insulating film. If the write/erase operation with respect to the nonvolatile memory is repeatedly performed, the damage of the interface becomes worse, the number of dangling bonds increases and electrons are trapped therein. Then, the trapped electrons are de-trapped at the charge holding time so as to cause the threshold value to vary and data held will be lost in the worst case in some cases. This is the model of deterioration in the charge holding characteristic and deterioration in the reliability.

However, the necessity for performing the wet oxidation process after formation of the SiN film leads to complication of the process and is not desirable. Further, when the LSI is miniaturized and it is required to lower the temperature in the manufacturing process, there occurs a problem that the high-temperature heat treatment in the wet atmosphere cannot be performed. In addition, an SiN film is used as a passivation film formed on the uppermost layer of the LSI in order to protect the LSI from disturbances such as moistures in the actual usage environment. The SiN film is formed by the plasma CVD method and is called a plasma SiN film. Active hydrogen is also discharged from the plasma SiN film and causes the reliability thereof to be lowered.

Thus, in the conventional nonvolatile semiconductor memory device, a coating insulating film such as an SiN film is used to protect the memory cell portion from disturbances such as metal impurities and moistures, but usage of the coating insulating film causes the charge holding characteristic of the memory cell portion to be lowered.

### BRIEF SUMMARY OF THE INVENTION

According to one aspect of the present invention, there is provided a semiconductor device comprising MOS transistors formed on a semiconductor substrate, and a coating insulating film formed to cover the surface portions of the transistors, wherein the insulating film is formed of one of a silicon nitride film and silicon oxynitride film and the ratio (N—H/Si—H) of the density of N—H bonds to the density of Si—H bonds in the insulating film is not higher than 3.

According to another aspect of the present invention, there is provided a nonvolatile semiconductor memory device comprising nonvolatile memory cells of transistor structures formed on a semiconductor substrate, each of the memory cells having a gate insulating film formed on the semiconductor substrate and a gate electrode formed on the gate insulating film, and a coating insulating film formed to cover the surface portions of the memory cells, wherein the insulating film is formed of one of a silicon nitride film and silicon oxynitride film and the ratio (N—H/Si—H) of the density of N—H bonds to the density of Si—H bonds in the insulating film is not higher than 3.

According to still another aspect of the present invention, there is provided a manufacturing method of a nonvolatile semiconductor memory device comprising forming nonvolatile memory cells of transistor structures each having a gate insulating film and gate electrode on a semiconductor substrate, and forming a coating insulating film formed to cover the surface portions of the memory cells, wherein the ratio (N—H/Si—H) of the density of N—H bonds to the density of Si—H bonds in the coating insulating film is not higher than 3.

### BRIEF DESCRIPTION OF THE SEVERAL VIEWS OF THE DRAWING

FIG. 1 is a plan view showing the cell array structure of a NAND flash memory according to one embodiment of this invention.

FIG. 2 is a diagram showing the circuit configuration of the NAND flash memory according to one embodiment of this invention.

FIGS. 3A to 3E are cross-sectional views taken along the line B-B′ of FIG. 1, for illustrating the manufacturing process of the NAND flash memory of FIG. 1.

FIGS. 4A to 4E are cross-sectional views taken along the line A-A′ of FIG. 1, for illustrating the manufacturing process of the NAND flash memory of FIG. 1.

FIG. 5 is a characteristic diagram showing an influence exerted by the ratio of the density of N—H bonds to the density of Si—H bonds on the threshold value variation amount characteristic.

FIG. 6 is a characteristic diagram showing an influence exerted by the density of N—H bonds on the threshold value variation amount characteristic.

### DETAILED DESCRIPTION OF THE INVENTION

Before explaining the present embodiment, the basic principle of this invention is explained.

As described before, a case wherein a barrier SiN film is formed to cover the surface of a memory cell portion, for example, when an SiN film is formed as a coating insulating film to protect the memory cell portion is considered. In this case, active hydrogen is discharged from the SiN film and introduced into a tunnel oxide film (SiO₂ film) used as a gate insulating film. As a result, the number of dangling bonds is increased and the charge holding characteristic is degraded. This also applies to a passivation film and active hydrogen discharged from the SiN film causes the charge holding characteristic to be degraded. Therefore, it is required to develop an SiN film that does not discharge active hydrogen.

On the other hand, it is preferable to discharge hydrogen in an H₂ molecule form instead of an active hydrogen form. The number of electron trap sites is reduced by causing the H₂ molecules to effectively make hydrogen termination with respect to dangling bonds of Si. In addition, the effect that the junction leak of the pn junction is reduced is attained.

The inventors of this application and others found the following phenomenon as the result of diligent studies and various experiments repeatedly performed based on the above estimation. That is, they found that the discharging amount of active hydrogen could be suppressed and H₂ molecules could be effectively discharged by adjusting the ratio of the density of N—H bonds to the density of Si—H bonds in the SiN film, and therefore, the charge holding characteristic of the nonvolatile memory cell could be enhanced.

Next, the embodiment of this invention using the above phenomenon is explained with reference to the embodiment shown in the drawings.

### EMBODIMENT

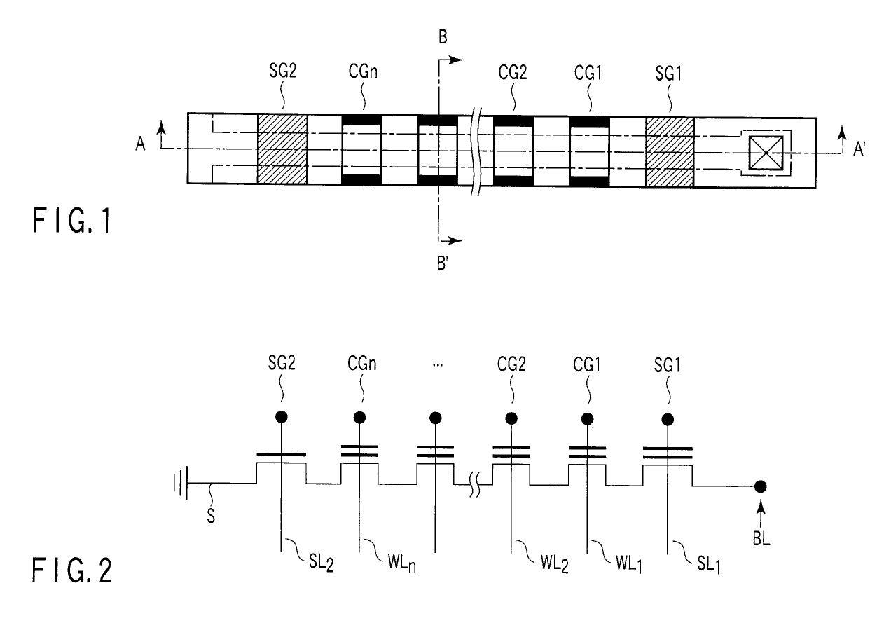

FIG. 1 is a plan view showing the cell array structure of a nonvolatile semiconductor memory device, for example, a NAND flash memory according to one embodiment of this invention. FIG. 2 is a diagram showing the circuit configuration of the above NAND flash memory.

A plurality of cell transistors CG1 to CGn each formed of an n-channel MOSFET having a floating gate (floating gate electrode) and control gate (control gate electrode) are serially connected. The drain on one-end side of the series-connected portion is connected to a bit line BL via an n-channel MOS transistor SG1 for cell selection. Further, the source on the other end side of the series-connected portion is connected to a source line S via an n-channel MOS transistor SG2 for cell selection.

The above transistors are formed on the same well substrate. The control gate electrodes of the cell transistors CG1 to CGn are respectively connected to word lines WL (WL1 to WLn) successively arranged in the row direction. The control gate electrode of the selection transistor SG1 is connected to a selection line SL1 and the control gate electrode of the selection transistor SG2 is connected to a selection line SL2. The word line WL has a structure formed on the element isolation insulating film. A bonding pad for connection with a peripheral circuit via a metal wiring is formed on one end of the word line WL.

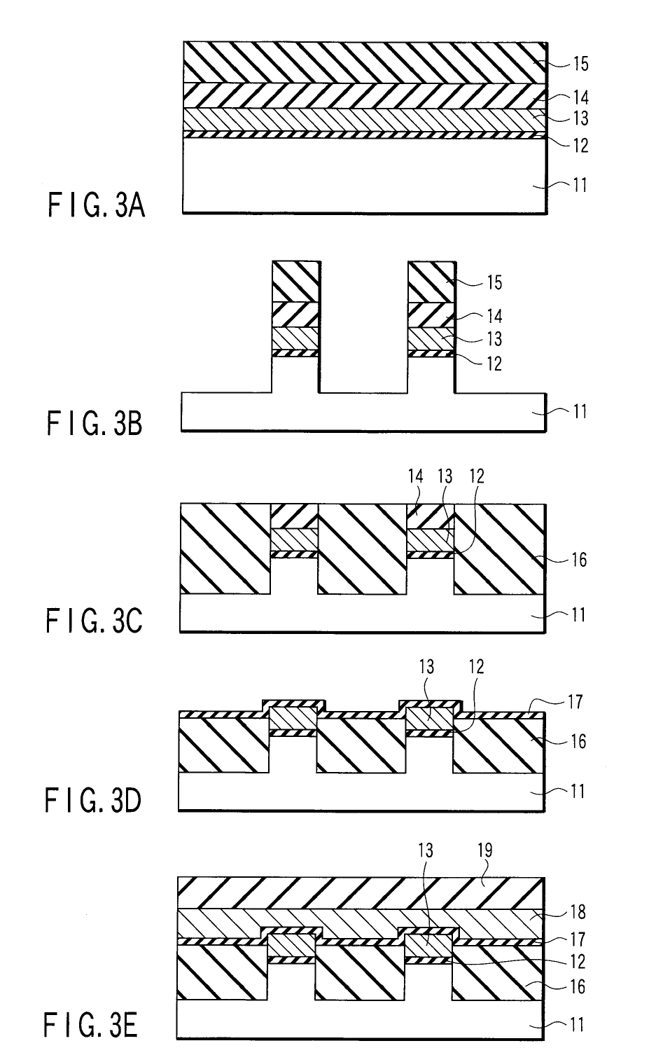

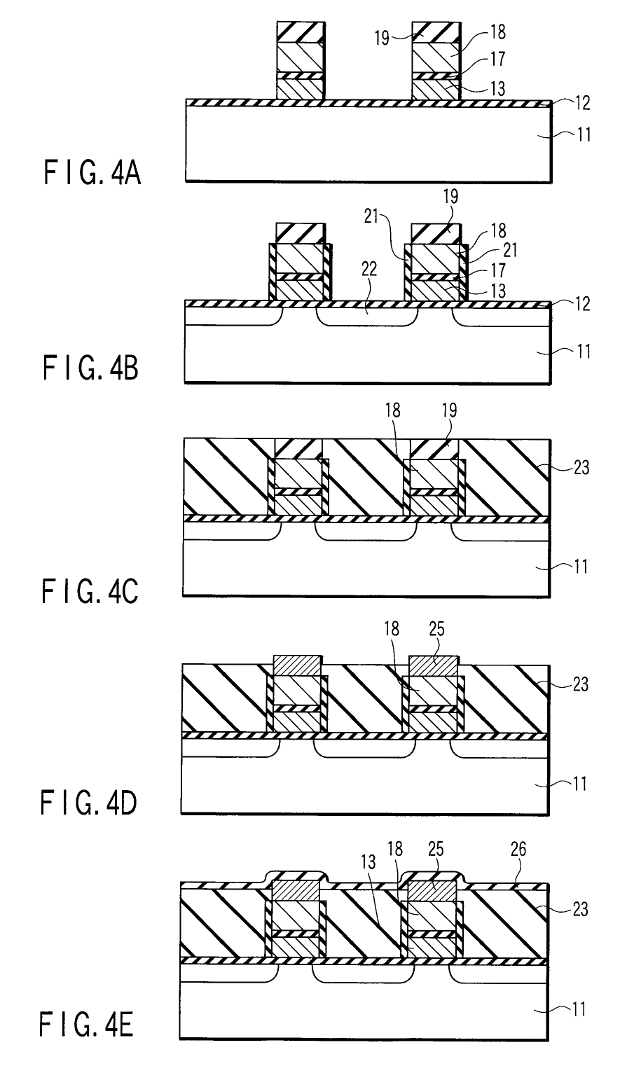

Next, the structure and the manufacturing process of the memory cell array of the present embodiment are explained with reference to FIGS. 3A to 3E and 4A to 4E. FIGS. 3A to 3E are cross-sectional views corresponding to the cross sections taken along the line B-B′ of FIG. 1 and FIGS. 4A to 4E are cross-sectional views corresponding to the cross sections taken along the line A-A′ of FIG. 1.

First, as shown in FIG. 3A, a silicon oxide film is formed on a silicon substrate 11 by use of a thermal oxidation method and then a silicon oxynitride film 12 is formed by nitriding the silicon oxide film by use of NH₃ gas. The silicon oxynitride film 12 functions as a first gate insulating film and is generally called a tunnel insulating film. Next, an amorphous silicon film 13, silicon nitride film 14 and silicon oxide film 15 are sequentially deposited on the silicon oxynitride film 12 by use of a CVD method. The amorphous silicon film 13 is a first gate electrode and is generally called a floating gate (floating gate electrode). As the silicon nitride film 14, the same film as the conventional DCS-SiN film can be used and an HCD-SiN film having the density of Si—H bonds of 3×10²¹/cm³ and the density of N—H bonds of 3×10²¹/cm³ as will be described later can be used. Further, oxygen may be contained in the silicon nitride film 14.

Next, as shown in FIG. 3B, the silicon oxide film 15 is selectively etched by use of a lithography method using photoresist (not shown) and then the silicon nitride film 14, amorphous silicon film 13 and silicon oxynitride film 12 are selectively etched with the silicon oxide film 15 used as a mask. Further, the surface portion of the silicon substrate 11 is selectively etched to form trenches.

After this, as shown in FIG. 3C, the inner walls of the trenches formed in the silicon substrate 11 are oxidized and a filling insulating film 16 which is formed of a silicon oxide film is deposited thereon by use of a plasma CVD method. Then, the filling insulating film 16 and silicon oxide film 15 are polished to the upper surface of the silicon nitride film 14 and the upper surface of the semiconductor structure is made flat by use of a CMP method.

Next, as shown in FIG. 3D, the upper surface of the filling insulating film 16 is lowered by use of the etching process until the upper surface of the filling insulating film 16 becomes lower than the upper surface of the amorphous silicon film 13. After this, a wet process to separate the silicon nitride film 14 is performed. After the element isolation structure is thus formed, an insulating film 17 formed of a silicon oxide film, silicon nitride film and silicon oxynitride film is formed on the floating gate 13 and filling insulating film 16. The insulating film 17 functions as a second gate insulating film and is generally called an electrode-electrode insulating film.

Then, as shown in FIG. 3E, an amorphous silicon film 18 is formed on the second gate insulating film 17 by use of an LPCVD method. The amorphous silicon film 18 is used as a second gate electrode and is generally called a control gate (control gate electrode). Next, a silicon nitride film 19 is formed on the control gate 18 by use of the LPCVD method.

After this, as shown in FIG. 4A, the silicon nitride film 19 is selectively etched by use of the lithography method using photoresist (not shown) and then the control gate 18, second insulating film 17 and floating gate 13 are sequentially etched in the vertical direction by use of the reactive ion etching (RIE) method with the silicon nitride film 19 used as a mask.

Next, as shown in FIG. 4B, silicon oxide films 21 are formed on the side walls of gate portions by use of a thermal oxidation method for the purpose of suppressing a leak current in the gate end portion. Generally, the oxidation process is called a post-oxidation process and the oxide film 21 formed at this time is called a post-oxidation film. After the post-oxidation film 21 is formed, ions are implanted into the silicon substrate 11 by an ion-implantation process to form source/drain regions 22 and then activated by a thermally annealing process.

Next, as shown in FIG. 4C, an interlayer insulating film 23 mainly formed of SiO₂ is filled into between adjacent gates.

After this, as shown in FIG. 4D, the silicon nitride films 19 on the control gates 18 are removed and then cobalt silicide films 25 are selectively formed on the control gates 18. Specifically, a Co film is formed on the entire surface of the control gates 18 and interlayer insulating film 23, then subjected to the heat treatment and formed into a silicide form. CoSi films 25 are formed only on the control gates 18 by removing the Co film that is not formed into the silicide form and is left behind.

Next, as shown in FIG. 4E, a silicon nitride film 26 that is the feature of this embodiment is formed on the interlayer insulating film 23 and cobalt silicide films 25. That is, the silicon nitride film (coating insulating film) 26 is formed by use of the CVD method as a barrier insulating film that covers the surface portion of the nonvolatile memory cells with the double-layered gate structures. After this, the multi-layered wiring process for BEOL is performed, but the process is omitted in the drawing.

In this example, a nitride film having the density of Si—H bonds of 3×10²¹/cm³ and the density of N—H bonds of 3×10²¹/cm³ is used as the silicon nitride film 26 used as a barrier insulating film that is the feature of this embodiment. The densities of the films are quantified by use of the Fourier Transform Infrared (FT-IR) method. In order to set the density of bonds as described above, the process is performed by using hexachlorodisilane (HCD: Si₂Cl₆) instead of the conventional DCS as a raw material used at the silicon nitride film formation time and adjusting the gas flow rate condition and temperature condition. In the following description, the nitride film formed by the above method is simply referred to as an HCD-SiN film.

Specifically, an HCD-SiN film is formed by causing HCD gas of 30 sccm and NH₃ gas of 1.2 slm to flow into a low-pressure chemical vapor deposition (LP-CVD) furnace of 550° C. and maintaining the pressure in the furnace at 50 Pa. The ratio of the density of Si—H bonds to the density of N—H bonds can be changed by changing the film formation temperature in the range of approximately 450 to 650° C.

Further, the ratio of the density of Si—H bonds to the density of N—H bonds can be changed in the same manner as described above by changing the gas flow rate ratio of Si₄ of raw material gas to NH₃ gas even when the plasma enhanced (PE) CVD method is used.

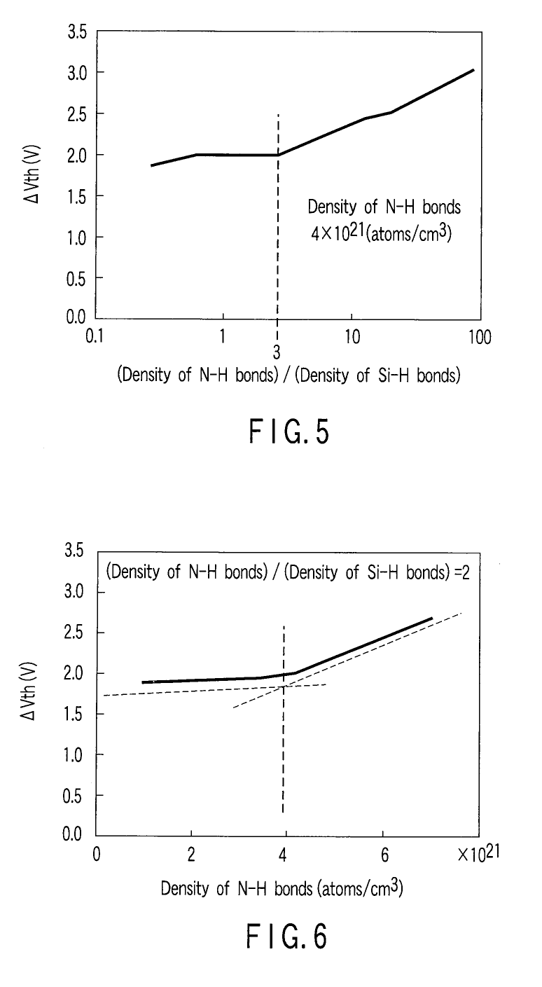

FIG. 5 shows an influence exerted by the ratio of the density of N—H bonds to the density of Si—H bonds on the reliability parameter of the memory cell portion. The ordinate indicates a threshold value variation amount (Endurance characteristic) ΔVth when the write/erase operation is repeatedly performed 1,000,000 times in the NAND flash memory and the abscissa indicates the ratio (N—H/Si—H) of the density of N—H bonds to the density of Si—H bonds. Since electrons are trapped in the tunnel insulating film when the write/erase operation is repeatedly performed, the threshold voltage rises. The ordinate indicates an index that indicates the density of trapped electrons. The fact that electrons are trapped in the tunnel insulating film increases the probability that the trapped electrons are de-trapped. That is, suppression of rise in the threshold voltage on the ordinate becomes one factor that enhances the reliability.

It is understood from FIG. 5 that the threshold value variation amount can be suppressed to a small value if the ratio of the density of N—H bonds to the density of Si—H bonds is set to 3 or less. When a film in which the ratio of the density of N—H bonds to the density of Si—H bonds is set approximately equal to “1” is used, the following reaction occurs if the film is subjected to the heat treatment.

N—H+Si—H→Si—N+H₂

Then, H₂ molecules are effectively discharged based on the reaction of Si—H bonds with adjacent N—H bonds. It is estimated that faults of the silicon oxynitride film 12 used as the tunnel insulating film or the level of the interface between the silicon substrate 11 and the silicon oxynitride film 12 is recovered by use of the H₂ molecules thus generated.

The above phenomenon is not limited to a case wherein the barrier insulating film 26 that covers the surface of the memory cell portion is a silicon nitride film, but can be applied to a case of a silicon oxynitride film. In the case of the silicon oxynitride film, it is confirmed that the threshold value variation amount is suppressed to a small value when the ratio of the density of N—H bonds to the density of Si—H bonds is set to 3 or less like the above case. Further, the same phenomenon is not limited to a case of the silicon oxynitride film and can be confirmed in the case of a silicon oxide film irrespective of the film type of the tunnel insulating film 12.

Thus, it is not recognized at all in the prior art that the ratio of the density of N—H bonds to the density of Si—H bonds exerts an influence on the reliability of the memory cell portion and this is found for the first time by the diligent studies of the inventors of this application and others. Further, the fact that the threshold value variation amount of the memory cell portion is suppressed to a small value by setting the ratio of the density of N—H bonds to the density of Si—H bonds to 3 or less is found for the first time by the experiments performed by the inventors of this application and others. It is more preferable to set the ratio of the density of N—H bonds to the density of Si—H bonds to 2 or less by taking the margin into consideration.

On the other hand, when a film in which the ratio of the density of N—H bonds to the density of Si—H bonds is high, H₂ molecules are also discharged based on the reaction of Si—H bonds with adjacent N—H bonds, but hydrogen radicals diverge from the N—H bonds that are large in absolute number. Therefore, the tunnel insulating film 12 will be damaged. In the case of a DCS-SiN film often used in the present semiconductor process, the density of N—H bonds is set to approximately 7×10²¹/cm³ and the density of Si—H bonds is set to approximately 1×10²¹/cm³ and the ratio of the densities of the bonds is set to approximately 7 to 10 although depending on the film formation condition. In the case of the above DCS-SiN film, the threshold value variation amount is large if it is used as it is, and therefore, it is necessary to perform the high-temperature heat treatment in a wet atmosphere in order to reduce the amount of hydrogen in the thin film.

In the case of the film in which the ratio of the density of N—H bonds to the density of Si—H bonds is set to 3 or less as in the present embodiment, since the amount of hydrogen radicals generated is small even if the film is used as it is, it becomes possible to reduce the number of high temperature heat treatments in the wet atmosphere. The fact that the high temperature heat treatment can be made unnecessary leads to an extremely effective effect that the process can be simplified and the heat damages of various layers already formed can be suppressed.

FIG. 6 is a diagram showing the relation between the threshold value variation amount (ΔVth) and the density of N—H bonds after the write/erase operation is repeatedly performed 1,000,000 times when the ratio of the density of N—H bonds to the density of Si—H bonds is set to 2. When the density of N—H bonds is set to 4×10²¹/cm³ or less, ΔVth is small and is set to 2.0 or less and when the density of N—H bonds exceeds 4×10²¹/cm³, ΔVth rapidly rises. Further, the same result is obtained even if the ratio of the density of N—H bonds to the density of Si—H bonds is changed in the range of 1 to 3. Therefore, it is understood that it is more preferable if the ratio of the density of N—H bonds to the density of Si—H bonds is set to 3 or less and the density of N—H bonds is set to 4×10²¹/cm³ or less.

Thus, according to the present embodiment, discharging or emission of hydrogen from the HCD-SiN film can be suppressed and the charge holding characteristic of the nonvolatile semiconductor memory cell can be enhanced by using a silicon nitride film (HCD-SiN film) in which the ratio of the density of N—H bonds to the density of Si—H bonds is set to 3 or less as a barrier insulating film of the memory cell. That is, the film quality of the coating insulating film used to protect the memory cell portion can be improved and the charge holding characteristic of the memory cell portion can be enhanced.

Since the HCD-SiN film can be formed at low temperatures, silicide that does not like the heat treatment at higher temperatures for formation of an SiN film will not be damaged even when cobalt silicide, nickel silicide or the like of low resistance is used as the control gate electrode. This is an effective effect when low-resistance silicide is used.

### MODIFICATION

This invention is not limited to the above embodiment. In the above embodiment, an example in which the silicon nitride film in which the ratio of the density of N—H bonds to the density of Si—H bonds is set to 3 or less is used as the barrier insulating film is explained. However, the film is not limited to the barrier insulating film and can be applied to a passivation film used as the uppermost layer of an LSI. Further, the silicon nitride film of this invention can be used as a side wall film of a field effect transistor or a diffusion prevention film before the wiring step. In addition, this invention is not necessarily limited to the silicon nitride film and can be applied to a silicon oxynitride film.

Further, the memory cell structure is not necessarily limited to the double-layered gate structure having the floating gate electrode and control gate electrode and can be applied to a nonvolatile memory cell such as a three-dimensional memory cell, MONOS having a tunnel insulating film or the like. In addition, the memory cell structure is applicable not only to the flat type described above but also to a nonvolatile memory cell having three dimensional structure. Furthermore, this invention is not necessarily limited to a nonvolatile semiconductor memory device and can be applied to a semiconductor device with the structure in which the surface portions of MOS transistors are covered with a coating insulating film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A MOSFET-type semiconductor device comprising:
MOS transistors formed on a semiconductor substrate, and
a coating insulating film formed to cover surface portions of the transistors,
wherein the insulating film is formed of one of a silicon nitride film and silicon oxynitride film and a ratio (N—H/Si—H) of density of N—H bonds to density of Si—H bonds in the insulating film is not higher than 3.

2. The semiconductor device according to claim 1, wherein the density of the N—H bonds in the insulating film is not higher than 4×10²¹/cm³.

3. The semiconductor device according to claim 1, wherein the ratio (N—H/Si—H) of the density of the N—H bonds to the density of the Si—H bonds in the insulating film is not higher than 2.

4. The semiconductor device according to claim 1, wherein the insulating film is formed by use of a CVD method using hexachlorodisilane (HCD) as raw material gas.

5. A nonvolatile semiconductor memory device comprising:
nonvolatile memory cells of transistor structures formed on a semiconductor substrate, each of the memory cells having a gate insulating film formed on the semiconductor substrate and a gate electrode formed on the gate insulating film, and
a coating insulating film formed to cover surface portions of the memory cells,
wherein the insulating film is formed of one of a silicon nitride film and silicon oxynitride film and a ratio (N—H/Si—H) of density of N—H bonds to density of Si—H bonds in the insulating film is not higher than 3.

6. The nonvolatile semiconductor memory device according to claim 5, wherein the density of the N—H bonds in the insulating film is not higher than 4×10²¹/cm³.

7. The nonvolatile semiconductor memory device according to claim 5, wherein the ratio (N—H/Si—H) of the density of the N—H bonds to the density of the Si—H bonds in the insulating film is not higher than 2.

8. The nonvolatile semiconductor memory device according to claim 5, wherein the coating insulating film is formed by use of a CVD method using hexachlorodisilane (HCD) as raw material gas.

9. The nonvolatile semiconductor memory device according to claim 5, wherein the memory cell has a double-layered gate structure in which a floating gate electrode and control gate electrode are stacked and the control gate electrode is formed of one of cobalt silicide and nickel silicide.

10. The nonvolatile semiconductor memory device according to claim 5, wherein every plural ones of the memory cells are serially connected to form a NAND cell unit.

11. A manufacturing method of a nonvolatile semiconductor memory device comprising:
forming nonvolatile memory cells of transistor structures each having a gate insulating film and gate electrode on a semiconductor substrate, and
forming a coating insulating film to cover surface portions of the memory cells,
wherein a ratio (N—H/Si—H) of density of N—H bonds to density of Si—H bonds in the coating insulating film is not higher than 3.

12. The manufacturing method according to claim 11, wherein the density of the N—H bonds in the insulating film is not higher than 4×10²¹/cm³.

13. The manufacturing method according to claim 11, wherein the ratio (N—H/Si—H) of the density of the N—H bonds to the density of the Si—H bonds in the insulating film is not higher than 2.

14. The manufacturing method according to claim 11, wherein the insulating film is formed by use of a CVD method using hexachlorodisilane (HCD) as raw material gas.

15. The manufacturing method according to claim 11, wherein the memory cell is formed to have a double-layered gate structure in which a floating gate electrode and control gate electrode are stacked and the control gate electrode is formed of one of cobalt silicide and nickel silicide.

16. The manufacturing method according to claim 11, wherein every plural ones of the memory cells are serially connected to form a NAND cell unit.
